(19) United States
(12) Patent Application Publication
(10) Pub. No.: US 2005/0279996 A1
(43) Pub. Date: Dec. 22, 2005

(54) Organic semiconductor element and manufacturing method thereof

(76) Inventors: Chiaki Takubo, Tokyo (JP); Hideo Aoki, Yokohama-shi (JP); Naoko Yamaguchi, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/152,373

(22) Filed: Jun. 15, 2005

(30) Foreign Application Priority Data
Jun. 16, 2004 (JP) P2004-177880

(51) Int. Cl. H01L 29/08; H01L 35/24; H01L 51/00; H01L 29/04; H01L 29/10; H01L 31/036

(52) U.S. Cl. 257/40; 257/57; 438/99; 257/149

(57) ABSTRACT

An organic semiconductor element comprises an organic semiconductor layer and an electrode supplying an electric current or an electric field to the organic semiconductor layer. The organic semiconductor layer includes a heat fusion layer of organic semiconductor particles. The heat fusion layer of the organic semiconductor particles is formed in such a manner that, for example, the organic semiconductor particles are made to adhere on a layer that is to be a base, by using an electrophotographic method, and thereafter, an adhesion layer of the organic semiconductor particles is heated to fusion bond the organic semiconductor particles. According to such an organic semiconductor element and a manufacturing method thereof, it is possible to enhance element manufacturing efficiency without an advantage of low cost and a miniaturization of an element structure.

### CROSS-REFERENCE TO RELATED APPLICATIONS

This application is based upon and claims the benefit of priority from the prior Japanese Patent Application No. 2004-177880, filed on Jun. 16, 2004; the entire contents of which are incorporated herein by reference.

### BACKGROUND

1. Field of the Invention

The present invention relates to an organic semiconductor element and a manufacturing method thereof.

2. Description of the Related Art

In recent years, studies on an organic semiconductor element utilizing an organic semiconductor material for its active layer have been rapidly progressing. As an organic semiconductor element, known is an organic thin film transistor (an organic TFT) of an field effect type in which an organic semiconductor layer is formed, via a gate insulation film, on a gate electrode provided on a resin substrate, and a source electrode and a drain electrode are formed thereon (for example, Japanese Patent Laid-open Application No. 0.2000-307172 and Japanese Patent Laid-open Application No. 2003-179234).

Unlike a conventional element using an inorganic semiconductor such as silicon, the organic semiconductor element is advantageous in that a low-cost printing method or the like is applicable to the formation of organic semiconductor layer. Another advantage of the organic semiconductor element is that its area can be easily made large. In addition, the organic semiconductor element has a characteristic that it can be made flexible element owing to flexibility of organic semiconductor layer itself and further because a resin substrate is usable when the printing method is used.

Organic semiconductor materials used for an organic semiconductor element are roughly classified into low-molecular organic semiconductor materials such as pentacene and high-molecular organic semiconductor materials such as polythiophene, polyfluorene, and polyphenylene vinylene. Since the high-molecular organic semiconductor materials such as polythiophene are superior in solubility in an organic solvent and the like, attempts have been made to use a printing method such as an ink jetting method, an offset printing method, or a gravure printing method for forming an organic semiconductor layer, with a high-molecular semiconductor material in a solution form being used as ink.

Among these printing methods, the ink jetting method is capable of direct drawing without using a mask or the like and is effective also for miniaturization of an element structure, but has a drawback of low efficiency in manufacturing an organic semiconductor element. The offset printing method and the gravure printing method, though highly efficient in manufacturing an organic semiconductor element, indispensably require the fabrication of a printing plate corresponding to an element structure. Therefore, manufacturing cost of the organic semiconductor element tends to increase and they are not suitable for fabricating organic semiconductor elements in small quantity and various kinds. Moreover, the offset printing and the gravure printing have a drawback that the element structure cannot be sufficiently miniaturized.

On the other hand, the low-molecular organic semiconductor materials such as pentacene are poor in solvent solubility, and therefore when the low-molecular organic semiconductor material is used to fabricate an organic semiconductor element, it is thought to be difficult to employ a printing method as is employed when the high-molecular organic semiconductor material is used. For fabricating an organic semiconductor element using the low-molecular organic semiconductor material, attempts have been made to apply a vacuum deposition process as in a conventional method of forming an inorganic semiconductor, but in this case, characteristics of a semiconductor element using the organic semiconductor material cannot be fully made use of. The low-molecular organic semiconductor materials have superior semiconductor characteristics over those of the high-molecular materials, and therefore, there has been a demand for development of low-cost manufacturing processes that can use a resin substrate and the like.

### SUMMARY

An organic semiconductor element according to one of the aspects of the present invention comprises: an organic semiconductor layer having a heat fusion layer of organic semiconductor particles; and an electrode supplying an electric current or an electric field to the organic semiconductor layer.

An organic semiconductor element according to another aspect of the present invention comprises: an organic semiconductor layer having a heat fusion layer of organic semiconductor particles; a gate electrode applying an electric field to the organic semiconductor layer; a gate insulation film interposed between the gate electrode and the organic semiconductor layer; a source electrode electrically connected to the organic semiconductor layer; and a drain electrode electrically connected to the organic semiconductor layer, a formation area of the gate electrode being sandwiched between the drain electrode and the source electrode.

A manufacturing method of an organic semiconductor element according to still another aspect of the present invention is a method of manufacturing an organic semiconductor element having an organic semiconductor layer, the method comprising: adhering organic semiconductor particles on a layer that is to be a base of the organic semiconductor layer; and heating the organic semiconductor particles to fusion bond the organic semiconductor particles, thereby forming the organic semiconductor layer.

### BRIEF DESCRIPTION OF THE DRAWINGS

The present invention will be described with reference to the drawings, but these drawings are provided only for an illustrative purpose and in no way are to limit the invention.

FIG. 1 is a sectional view schematically showing a rough structure of an organic semiconductor element according to a first embodiment of the present invention.

FIG. 2 is a view showing a structural example of a dry development type image forming apparatus used in manufacturing processes of the organic semiconductor element according to the first embodiment of the present invention.

FIG. 3 is a view showing a structural example of a liquid development type image forming apparatus used in the manufacturing processes of the organic semiconductor element according to the first embodiment of the present invention.

FIG. 4A and FIG. 4B are sectional views schematically showing manufacturing processes of an organic semiconductor layer in the organic semiconductor element shown in FIG. 1.

FIG. 5 is a sectional view schematically showing a rough structure of a modification example of the organic semiconductor element according to the first embodiment of the present invention.

FIG. 6 is a sectional view schematically showing a rough structure of another modification example of the organic semiconductor element according to the first embodiment of the present invention.

FIG. 7A, FIG. 7B, FIG. 7C, FIG. 7D, and FIG. 7E are sectional views schematically showing manufacturing processes of the organic semiconductor element according to the first embodiment of the present invention.

FIG. 8 is a sectional view schematically showing a rough structure of an organic semiconductor element according to a second embodiment of the present invention.

### DETAILED DESCRIPTION

Hereinafter, embodiments of the present invention will be described with reference to the drawings. It should be noted that, though the embodiments of the present invention will be described based on the drawings, these drawings are provided only for an illustrative purpose and in no way are to limit the present invention.

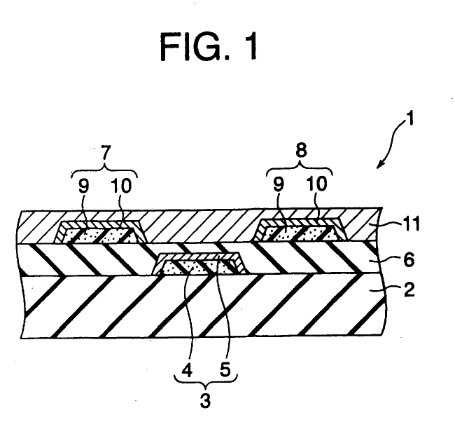

FIG. 1 is a sectional view showing a rough structure of an organic semiconductor element according to a first embodiment of the present invention. An organic semiconductor element 1 shown in the drawing has a substrate 2 made of, for example, an insulation resin. In particular, a flexible resin substrate such as an insulation resin film is effective for making full use of characteristics of the organic semiconductor element 1 and is preferable also from the viewpoint of reducing manufacturing cost, expanding applicable fields, and so on of the organic semiconductor element 1. However, a constituent material of the substrate 2 is not limited to the insulation resin, but substrates made of various kinds of insulative materials are usable.

A gate electrode 3 is formed on the substrate 2. The gate electrode 3 includes, for example, a plating seed layer 4 and a metal plating layer 5 formed on a surface of the plating seed layer 4. However, the gate electrode 3 is not limited to this structure, but may be formed by, for example, a printing method, a deposition method, a sputtering method, or the like. A gate insulation film 6 is formed on the gate electrode 3. That is, a surface of the substrate 2 including a surface of the gate electrode 3 is covered with the gate insulation film 6. The gate insulation film 6 is made of, for example, insulation resin such as polyvinylphenol, polyimide, or fluorine resin, or an inorganic insulative substance such as SiO₂ or Si₃N₄.

A source electrode 7 and a drain electrode 8 are arranged on the gate insulation film 6, being a predetermined distance apart from each other. Specifically, the source electrode 7 and the drain electrode 8 are formed so that a formation area of the gate electrode 3 is sandwiched therebetween. Similarly to the gate electrode 3, each of these electrodes 7, 8 includes a plating seed layer 9 and a metal plating layer 10 formed on a surface of the plating seed layer 9. Similarly to the gate electrode 3, the source electrode 7 and the drain electrode 8 are not limited to such a structure either. The substrate 2 having the electrodes 3, 7, 8 and the gate insulation film 6 can be fabricated through the use of an image forming apparatus employing an electrophotographic method, as will be described later. However, a printing method, a laminating method, or the like may be used for forming such a substrate 2.

An organic semiconductor layer 11 as an active layer is formed on the source electrode 7 and the drain electrode 8 so as to cover the entire gate insulation film 6 including surfaces of the source electrode 7 and the drain electrode 8. As a constituent material of the organic semiconductor layer 11, usable is, for example, a high-molecular organic semiconductor material such as polychiophene, polyfluorene, or polyphenylene vinylene, and further usable is a low-molecular organic semiconductor material such as pentacene. The organic semiconductor layer 11 is formed of particles of such an organic semiconductor material (organic semiconductor particles) turned into a layer form by heat fusion.

The organic semiconductor layer 11 is formed in such a manner that the organic semiconductor particles are made to adhere on the gate insulation film 6 which is to be a base layer of the organic semiconductor layer 11 and which has the source electrode 7 and the drain electrode 8 thereon, and heat treatment is applied to an adhesion layer of the organic semiconductor particles to fusion bond the organic semiconductor particles. The electrophotographic method is preferably used for the adhesion process of the organic semiconductor particles onto the gate insulation film 6. This can enhance element manufacturing efficiency, reproducibility of a minute pattern, and so on.

Incidentally, the method employed in the adhesion process of the organic semiconductor particles is not limited to the electrophotographic method, but the adhesion process may be conducted by, for example, applying a liquid substance in which the organic semiconductor particles are dispersed and drying the liquid substance. In any way, it is important to make the organic semiconductor material in a particle form adhere on the layer that is to be the base, and whereby, it is possible to form the organic semiconductor layer 11 while maintaining characteristics of the organic semiconductor material. Further, when the low-molecular organic semiconductor material poor in solvent solubility is used, it is also possible to form the organic semiconductor layer 11 without using a vacuum deposition process or the like.

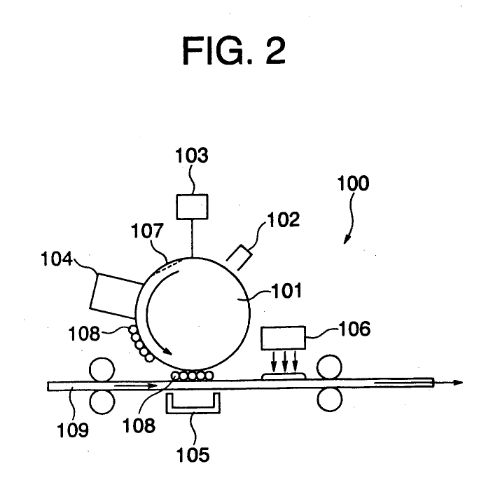

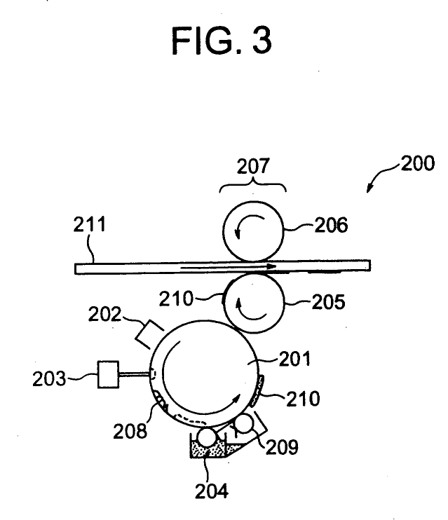

When the electrophotographic method is used for forming the organic semiconductor layer 11, an electrophotographic image forming apparatus as shown in, for example, FIG. 2 or FIG. 3 is used. FIG. 2 shows a structural example of a dry development type image forming apparatus 100 employing the electrophotographic method. The image forming apparatus 100 is mainly composed of a photoconductor drum 101, a charging unit 102, an exposure unit 103, a dry development unit 104, a transfer unit 105, and a fuser unit 106. Toner particles including organic semiconductor particles are stored in the dry development unit 104. An average particle size of the organic semiconductor particles forming a toner is preferably in a range from 0.5 μm to 20 μm. When the dry development unit 104 is used, an average particle size of the organic semiconductor particles is preferably in a range from 3 μm to 20 μm.

FIG. 3 shows a structural example of a liquid (wet) development type image forming apparatus 200 employing the electrophotographic method. The image forming apparatus 200 is mainly composed of a photoconductor drum 201, a charging unit 202, an exposure unit 203, a liquid development unit 204, and a transfer/fuser unit 207 in which an intermediate transfer roller 205 and a pressure/heating roller 206 are provided. The liquid development unit 204 stores a liquid developer being a dielectric liquid (isopar) with toner particles of organic semiconductor particles suspended therein. When the liquid development unit 204 is used, an average particle size of the organic semiconductor particles forming the toner particles is preferably in a range from 0.1 μm to 3 μm, and more preferably, in a range from 0.1 μm to 0.5

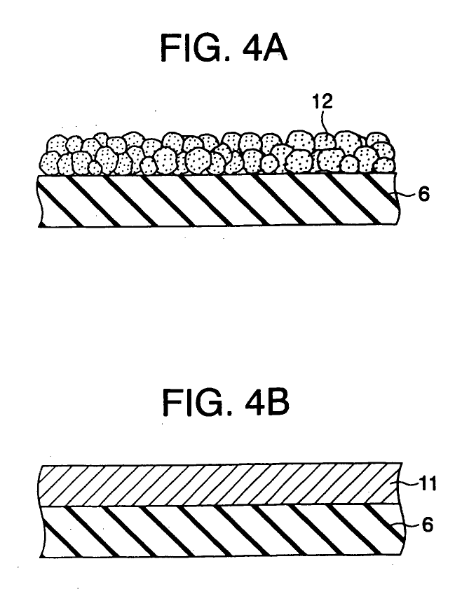

Processes of forming the organic semiconductor layer 11 using such image forming apparatuses will be described with reference to FIG. 4A and FIG. 4B. First, an example where the dry development type image forming apparatus 100 shown in FIG. 2 is used will be described. While the photoconductor drum 101 is being rotated in an arrow direction, the charging unit 102 charges the photoconductor drum 101 to a predetermined surface potential (for example, minus charges). A specific charging method available is scorotron charging, roller charging, brush charging, or the like. Next, by the exposure unit 103 to which, for example, a laser generator/scanner is applied, the photoconductor drum 101 is irradiated with a laser beam according to an image signal, so that the minus charges in an irradiation portion are removed. Consequently, an image of charges (electrostatic latent image) 107 corresponding to a predetermined element pattern is formed on a surface of the photoconductor drum 101.

Next, the dry development unit 104 supplies the toner particles, that is, the charged organic semiconductor particles, which are then made to adhere on the electrostatic latent image 107 on the photoconductor drum 101, so that a visible image 108 is formed. At this time, charged area development or reversal development is usable. Further, a dry type toner transfer technique in a known electrophotographic copying system is applicable to the dry development unit 104. Subsequently, by the transfer unit 105, the visible image 108 formed by the organic semiconductor particles (toner particles) is transferred onto a base sheet 109 from the photoconductor drum 101. As a transfer method, electrostatic transfer, adhesive transfer, pressure transfer, and the like are known, and any of them may be employed.

Specifically, as shown in FIG. 4A, organic semiconductor particles 12 used as toner particles are transferred and made to adhere onto the substrate having the gate insulation film 6 that is to be the base sheet 109, according to a formation pattern of the organic semiconductor layer 11. Next, the organic semiconductor particles 12 transferred onto the gate insulation film 6 are heated and fixed by the fuser 106. In this heat fixation, at least surface portions of the organic semiconductor particles 12 are melted or softened, thereby fusion bonding the adjacent organic semiconductor particles 12. In this manner, as shown in FIG. 4B, the organic semiconductor layer 11 made of a heat fusion layer of the organic semiconductor particles 12 is formed. Incidentally, the transfer process and the heat fixation process of the organic semiconductor particles 12 may be repeated a plurality of times according to the thickness or the like of the organic semiconductor layer 11.

When the liquid development type image forming apparatus 200 shown in FIG. 3 is used, charging by the charging unit 202 and forming of an electrostatic latent image 208 by the exposure unit 203 are conducted while the photoconductor drum 201 is being rotated in an arrow direction, in the same manner aswhen the dry development type image forming apparatus 100 is used. Next, the liquid development unit 204 supplies a liquid developer being a dielectric liquid (isopar) with organic semiconductor particles suspended therein as toner particles, which is then made to adhere onto the electrostatic latent image 208 on the photoconductor drum 201. A squeeze unit 209 provided in the liquid development unit 204 removes an excessive liquid, so that a visible image 210 is formed on a surface of the photoconductor drum 201.

Next, the visible image 210 formed by the organic semiconductor particles (toner particles) is once transferred to the intermediate transfer roller 205. Subsequently, the visible image 210 transferred to the intermediate transfer roller 205 is transferred onto a base sheet 211 while the base sheet 211 is pressed and heated from a rear side thereof by the pressure/heating roller 206. At this time, the visible image 210 formed by the organic semiconductor particles are heated and fixed simultaneously with the transfer onto the base sheet 211. In this manner, as shown in FIG. 4A and FIG. 4B, the adhesion process of the organic semiconductor particles 12 and the formation process of the heat fusion layer (organic semiconductor layer 11) of the organic semiconductor particles 12 are conducted.

In the above-described organic semiconductor element 1, the source electrode 7 and the drain electrode 8 are electrically connected to each other via the organic semiconductor layer 11. An electric current supplied from the source electrode 7 to the organic semiconductor layer 11 is discharged from the drain electrode 8. The gate electrode 3 is arranged with the gate insulation film 6 being interposed between the gate electrode 3 and the organic semiconductor layer 11 so as to be capable of applying an electric field to the organic semiconductor layer 11 connecting the source electrode 7 and the drain electrode 8. The organic semiconductor element 1 functions as a field effect transistor (FET) that controls the electric current between the source electrode 7 and the drain electrode 8 based on ON/OFF of voltage to the gate electrode 3. That is, the organic semiconductor element 1 constitutes an organic TFT functioning as a switching element or the like.

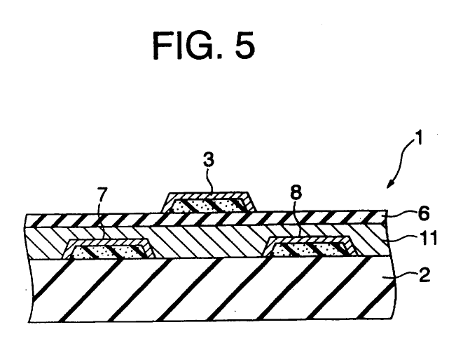

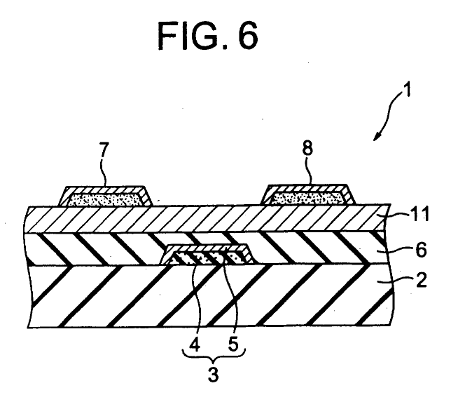

Incidentally, element structures shown in, for example, FIG. 5 and FIG. 6 may be applied to the organic semiconductor element 1. An organic semiconductor element 1 shown in FIG. 5 has an element structure such that a source electrode 7 and a drain electrode 8 are formed on a substrate 2, and an organic semiconductor layer 11, a gate insulation film 6, and a gate electrode 3 are formed thereon in this order. An organic semiconductor element 1 shown in FIG. 6 has an element structure such that an organic semiconductor layer 11 is formed on a gate insulation film 6 and a source electrode 7 and a drain electrode 8 are formed thereon. In this case, the source electrode 7 and the drain electrode 8 may be formed by a printing method or the like.

Among the aforesaid structures, the element structure shown in FIG. 1 or FIG. 5 is preferably applied to the organic semiconductor element 1. In the organic semiconductor element 1 shown in FIG. 1, the formation process of the organic semiconductor layer 11 is a final process. Therefore, even when a plating method is applied to the formation processes of the electrodes 3, 7, 8, characteristic deterioration of the organic semiconductor layer 11 can be prevented. In the organic semiconductor element 1 shown in FIG. 5, when the electrode 3 is formed on the organic semiconductor layer 11, the gate insulation film 6 functions as a protective layer of the organic semiconductor layer 11. Therefore, characteristic deterioration of the organic semiconductor layer 11 is prevented.

In the above-described first embodiment, since the heat fusion layer of the organic semiconductor particles is used in the organic semiconductor layer 11, it is possible to use various kinds of organic semiconductor materials for forming the organic semiconductor layer 11 while maintaining semiconductor characteristics of the organic semiconductor materials. Moreover, it is possible to realize reduced manufacturing cost, improved manufacturing efficiency, and so on of the organic semiconductor element 1. For example, not only when the high-molecular organic semiconductor material is used but also when the low-molecular organic semiconductor material poor in solvent solubility or the like is used, it is also possible to manufacture the minute organic semiconductor layer 11 with good reproducibility and at low cost while maintaining semiconductor characteristics that the organic semiconductor particles have in themselves.

In particular, the use of the electrophotographic method in the adhesion process of the organic semiconductor particles makes it possible to enhance manufacturing efficiency of the organic semiconductor element 1 without impairing an advantage of low cost and the like owing to formability of a minute pattern and direct drawing thereof. That is, according to the electrophotographic method, it is possible to make the organic semiconductor particles directly adhere on the base sheet (base) according to the formation pattern of the organic-semiconductor layer 11 without using any mask or printing plate. It is possible to obtain the minute organic semiconductor layer 11 with good reproducibility by heat fixation of the adhesion layer of such organic semiconductor particles. Therefore, it is possible to enhance manufacturing efficiency of the organic semiconductor element 1 without impairing an advantage of low cost and the like owing to formability of a minute pattern and direct drawing thereof.

The organic semiconductor element 1 of this embodiment is applicable to various kinds of electric/electronic devices. For example, the organic semiconductor element 1 is used as a switching element and a circuit element in a display device such as a liquid crystal display and an organic EL display, a sheet-type sensor such as an optical sensor and a pressure sensitive sensor, a power generator such as a solar battery, and a data carrier component such as an RF tag. The organic semiconductor layer 11 including the heat fusion layer of the organic semiconductor particles is applicable not only to the FET but also to other semiconductor elements with a three-terminal structure such as a bipolar transistor.

Further, the organic semiconductor layer 11 is also applicable to a semiconductor element with a two-terminal structure such as an organic diode and an organic thyristor. In the organic diode and the organic thyristor, a layered film of a p-type organic semiconductor layer and an n-type organic semiconductor layer is formed of a heat fusion layer of organic semiconductor particles. By providing an anode and a cathode in such a layered film (organic semiconductor layer), an organic semiconductor element with a two-terminal structure is formed. The organic diode is used as, for example, a photoreceptor used in an optical sensor and a solar battery, a light emitting element used in an organic EL display.

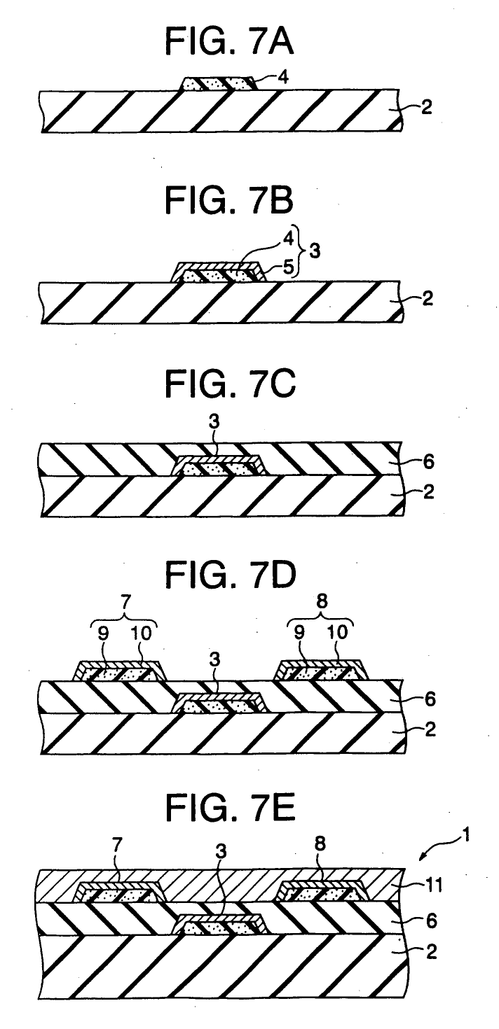

The above-described formation process of the organic semiconductor layer 11, that is, the formation process of the organic semiconductor layer 11 using the electrophotographic method is applicable to formation processes of the electrodes 3, 7, 8 (concretely, the formation processes of the plating seed layers) and a formation process of the gate insulation film 6. That is, the electrophotographic method can be used in the whole fabrication processes of the organic semiconductor element 1. The fabrication processes of the organic semiconductor element 1 using such an electrophotographic method will be described with reference to FIG. 7A to FIG. 7E.

First, as shown in FIG. 7A, the plating seed layer 4 of the gate electrode 3 is formed on the substrate 2 by using the electrophotographic method. When the electrophotographic method is used for forming the plating seed layer 4, insulation resin particles containing metal particulates (metal-containing resin particles) are used as a toner. As the metal-containing resin particles, used are particles made of, for example, thermosetting resin such as B-stage epoxy resin containing metal particulates of Pt, Pd, Cu, Au, Ni, Ag or the like. The metal particulates in the resin particles will serve as nuclei of plating. The electrophotographic image forming apparatus shown in FIG. 2 or FIG. 3 is employed in the layer formation process when the metal-containing resin particles are used as is employed when the organic semiconductor particles are used.

For example, in the image forming apparatus 100 shown in FIG. 2, by the exposure unit 103, an electrostatic latent image 107 with a predetermined pattern is formed on the photoconductor drum 101 charged to a predetermined potential. The electrostatic latent image 107 is formed to correspond to a formation pattern of the gate electrode 3. The toner made of the metal-containing resin particles is supplied from the development unit 104, and the electrostatic latent image 107 is made to adhere on the photoconductor drum 101. Subsequently, in the transfer unit 105, a visible image 108 formed on the surface of the photoconductor drum 101 is transferred onto the base sheet 109. Next, the toner of the metal-containing resin particles transferred onto the base sheet 109 is heated and fixed by the fuser 106. The B-stage thermosetting resin is cured by the heating.

In this manner, the plating seed layer 4 made of the insulation resin layer containing the metal particulates is formed on the substrate 2. Processes when the image forming apparatus 200 shown in FIG. 3 is used are also the same. Next, as shown in FIG. 7B, the plating seed layer 4 is subjected to electroless plating, so that the metal plating layer 5 to be an electrode layer is formed. An electroless plating bath, though not shown in FIG. 2, is disposed on a subsequent stage of the fuser 106. The substrate 2 having the plating seed layer 4 is immersed in the electroless plating bath containing Cu or the like, so that metal such as Cu is selectively precipitated with the metal particulates protruding to a surface of the plating seed layer 4 serving as nuclei. Through such an electroless plating process, the gate electrode 3 having the metal plating layer 5 is formed.

Next, as shown in FIG. 7C, the gate insulation film 6 is formed on the gate electrode 3 by using the electrophotographic method. When the electrophotographic method is used for forming the gate insulation film 6, insulation resin particles of, for example, polyvinylphenol, polyimide, fluorine resin, or the like are used as a toner. With the use of such a toner made of the insulation resin particles, the development of an electrostatic latent image by the toner, the transfer of a visible image formed by the toner, and heat fixation of a transferred image are conducted in the same manner as when the plating seed layer 4 is formed. Consequently, the gate insulation film 6 made of an insulation resin layer is formed on the gate electrode 3. Note that for the heat fixation of the transferred image, the toner made of the thermosetting resin is cured by heating to be fixed. When a toner made of thermoplastic resin is used, for example, heat fusion is caused for fixation.

Next, as shown in FIG. 7D, the source electrode 7 and the drain electrode 8 are formed on the gate insulation film 6. The formation processes of the source electrode 7 and the drain electrode 8 are conducted in the same manner as in the formation process of the gate electrode 3. Specifically, the plating seed layers 9 of the source electrode 7 and the drain electrode 8 are formed on the gate insulation film 6, and metal such as Cu is selectively precipitated by electroless plating with metal particulates protruding to the surfaces of the plating seed layers 9 serving as nuclei. In such a manner, the source electrode 7 and the drain electrode 8 each having the metal plating layer 10 are formed. Thereafter, the organic semiconductor layer 11 is formed on the gate insulation film 6 by using the electrophotographic method. The organic semiconductor layer 11 is formed through the processes as described previously.

Note that for forming the organic semiconductor element 1 shown in FIG. 5, the electrophotographic method is used to form the organic semiconductor layer 11 on the substrate 2 on which the source electrode 7 and the drain electrode 8 are provided. The formation processes of the organic semiconductor layer 11 in this case can be conducted in the same manner in FIG. 4A and FIG. 4B except that a base layer is the substrate 2 on which the source electrode 7 and the drain electrode 8 are provided. When the electrophotographic method is used for forming the source electrode 7 and the drain electrode 8 in the organic semiconductor element 1 shown in FIG. 6, organic semiconductor particles containing metal particulates are preferably used as a toner to form the plating seed layers 10. This makes it possible to maintain good electrical connection of the organic semiconductor layer 11 to the source electrode 7 and the drain electrode 8.

In the above-described manufacturing processes of the organic semiconductor element 1, the electrophotographic method is used in all of the manufacturing processes of the gate electrode 3, the gate insulation film 6, the source electrode 7, the drain electrode 8 and the organic semiconductor layer 11. This enables efficient and low-cost manufacturing of the whole organic semiconductor element 1. This also enables miniaturization of the whole element structure of the organic semiconductor element 1. Therefore, downsizing/higher density, higher performance, reduced cost, and soon of the organic semiconductor element 1 can be realized.

The manufacturing processes of the organic semiconductor element of this embodiment are applicable not only to the FET but also to other semiconductor element with a three-terminal structure or a semiconductor element with a two-terminal structure such as an organic diode. The electrophotographic method is applicable to fabrication processes of organic semiconductor elements with various kinds of structures, and in any case, it is possible to manufacture the whole element at low cost and with high efficiency. Therefore, according to the manufacturing processes of this embodiment, it is possible to realize downsizing/higher density, higher performance, reduced cost, and so on of organic semiconductor elements with various kinds of structures.

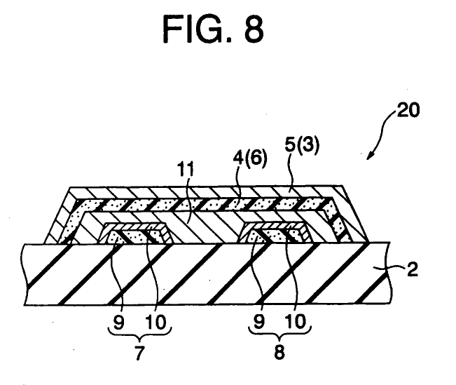

Next, anorganic semiconductor element according to a second embodiment of the present invention will be described with reference to FIG. 8. The same reference numerals are used to designate the same portions as those of the first embodiment described above, and description thereof will be partly omitted. In an organic semiconductor element 20 shown in FIG. 8, a source electrode 7 and a drain electrode 8 each having a plating seed layer 9 and a metal plating layer 10 are formed on a substrate 2. These electrodes 7, 8 are formed by the electrophotographic method similarly to the first embodiment described above.

An organic semiconductor layer 11 as an active layer is formed on the source electrode 7 and the drain electrode 8. As a constituent material of the organic semiconductor layer 11, usable is, for example, a high-molecular organic semiconductor material such as polythiophene, polyfluorene, or polyphenylene vinylene, or a low-molecular organic semiconductor material such as pentacene, as in the first embodiment. The organic semiconductor layer 11 is made by heat fusion of particles of such an organic semiconductor material. Specifically, the organic semiconductor layer 11 is formed in a layer form in such a manner that organic semiconductor particles are made to adhere on the substrate 2 having the source electrode 7 and the drain electrode 8, and heat treatment is applied to an adhesion layer of the organic semiconductor particles to fusion bond the organic semiconductor particles. Concrete formation processes are the same as those in the first embodiment.

A plating seed layer 4 of the gate electrode 3 is formed on the organic semiconductor layer 11 including a heat fusion layer of the organic semiconductor particles. A metal plating layer 5 functioning as the gate electrode 3 is formed on the plating seed layer 4. The plating seed layer 4 is formed by the electrophotographic method as in the above-described first embodiment. Here, the plating seed layer 4 is made of an insulation resin layer containing metal particulates, and the whole plating seed layer 4 functions as an insulation layer. Therefore, since the metal particulates to serve as plating nuclei are dispersed in the insulation resin layer in the plating seed layer 4, a function as the insulation layer is maintained in the plating seed layer 4 itself.

In the organic semiconductor element 20 of the second embodiment, the plating seed layer 4 having the function as the insulation layer is utilized as a gate insulation film 6. Specifically, the metal plating layer 5 functioning as the gate electrode 3 is formed on the organic semiconductor layer 11 via the gate insulation film 6 made of the plating seed layer 4. In other words, on the organic semiconductor layer 11 connecting the source electrode 7 and the drain electrode 8, the gate electrode 3 is disposed via the gate insulation film 6 made of the plating seed layer 4, and an electric field is applied from the gate electrode 3. The organic semiconductor element 20 functions as a field effect transistor as in the first embodiment.

In the organic semiconductor element 20 of the above-described second embodiment, the plating seed layer 4 is utilized as the gate insulation film 6, so that the number of layers constituting the element is reduced. Therefore, manufacturing cost of the organic semiconductor element 20 can be further reduced. Further, as in the first embodiment, the organic semiconductor layer 11 including the heat fusion layer of the organic semiconductor particles is adopted, so that it is possible to fabricate at low cost the layer 11 made of the organic semiconductor materials of various kinds while maintaining semiconductor characteristics thereof. Further, since the electrophotographic method is used in the adhesion process of the organic semiconductor particles, it is possible to enhance manufacturing efficiency of the organic semiconductor element 20 without impairing an advantage of low cost or the like owing to formability of a minute pattern and direct drawing thereof.

It should be noted that the present invention is not limited to the above-described embodiments, but any organic semiconductor element utilizing an organic semiconductor layer as its active layer and a manufacturing method thereof are included in the present invention. Further, any expansion and modification of the embodiments of the present invention may be made within a technical spirit of the present invention, and the expanded and modified embodiments are also included in the technical scope of the present invention.

1. An organic semiconductor element, comprising:
an organic semiconductor layer having a heat fusion layer of organic semiconductor particles; and
an electrode supplying an electric current or an electric field to said organic semiconductor layer.

2. The organic semiconductor element as set forth in claim 1,
wherein an average particle size of said organic semiconductor particles is in a range from 0.5 μm to 20 μm.

3. The organic semiconductor element as set forth in claim 1,
wherein said organic semiconductor layer is formed on an insulation resin substrate directly or via another layer.

4. The organic semiconductor element as set forth in claim 1,
wherein said electrode comprises a plating seed layer having an insulation resin layer or an organic semiconductor layer which contain metal particulates, and a metal plating layer formed on the plating seed layer.

5. An organic semiconductor element, comprising:
an organic semiconductor layer having a heat fusion layer of organic semiconductor particles;
a gate electrode applying an electric field to said organic semiconductor layer;
a gate insulation film interposed between said gate electrode and said organic semiconductor layer;
a source electrode electrically connected to said organic semiconductor layer; and
a drain electrode electrically connected to said organic semiconductor layer and arranged so that a formation area of said gate electrode is sandwiched between said drain electrode and said source electrode.

6. The organic semiconductor element as set forth in claim 5,
wherein at least one selected from said gate electrode, said source electrode and said drain electrode comprises a plating seed layer having an insulation resin layer or an organic semiconductor layer which contain metal particulates, and a metal plating layer formed on the plating seed layer.

7. The organic semiconductor element as set forth in claim 5,
wherein said gate insulation film includes an insulation resin layer.

8. The organic semiconductor element as set forth in claim 5,
wherein said gate insulation film is formed to cover a surface of a substrate having said gate electrode, and said organic semiconductor layer is formed to cover said source electrode and said drain electrode which are formed on said gate insulation film.

9. The organic semiconductor element as set forth in claim 5,
wherein said organic semiconductor layer is formed to cover a surface of a substrate having said source electrode and said drain electrode, said gate insulation film is formed on the organic semiconductor layer, and said gate electrode is formed on said gate insulation film.

10. The organic semiconductor element as set forth in claim 9,
wherein said gate insulation film has an insulation resin layer containing metal particulates, and said gate electrode has a metal plating layer which is formed using said gate insulation film as a plating seed layer.

11. A manufacturing method of an organic semiconductor element having an organic semiconductor layer, the method comprising:
adhering organic semiconductor particles on a layer that is to be a base of the organic semiconductor layer; and
heating the organic semiconductor particles to fusion bond the organic semiconductor particles.

12. The manufacturing method of the organic semiconductor element as set forth in claim 11,
wherein said organic semiconductor particles are made to adhere on the base layer by an electrophotographic method.

13. The manufacturing method of the organic semiconductor element as set forth in claim 12,
wherein said organic semiconductor particles adhering process comprises: exposing a photoconductor based on image information of the organic semiconductor layer to form an electrostatic latent image on the photoconductor; developing the electrostatic latent image on the photoconductor with toner particles containing the organic semiconductor particles to form a toner image on the photoconductor; and transferring onto the base layer the toner image on the photoconductor.

14. The manufacturing method of the organic semiconductor element as set forth in claim 13,
wherein said developing process comprises a process of dry developing the electrostatic latent image with the toner particles containing the organic semiconductor particles, an average particle size of the organic semiconductor particles being in a range from 3 μm to 20 μm.

15. The manufacturing method of the organic semiconductor element as set forth in claim 13,
wherein said developing process comprises a process of liquid developing the electrostatic latent image with a liquid developer made of a dielectric liquid in which the organic semiconductor particles are suspended as the toner particles, an average particle size of the organic semiconductor particles being in a range from 0.1 μm to 3 μm.

16. The manufacturing method of the organic semiconductor element as set forth in claim 11, further comprising:
forming an electrode supplying an electric current or an electric field to the organic semiconductor layer.

17. The manufacturing method of the organic semiconductor element as set forth in claim 16, wherein said the electrode forming process comprises:
adhering insulation resin particles or organic semiconductor particles in which metal particulates are dispersed on the layer that is to be a base of the electrode, by using an electrophotographic method; heating the insulation resin particles or the organic semiconductor particles to form a plating seed layer; and applying electroless plating to the plating seed layer to form a metal plating layer.

18. The manufacturing method of the organic semiconductor element as set forth in claim 11, further comprising:
forming a source electrode and a drain electrode which supply an electric current to the organic semiconductor layer;
forming a gate electrode applying an electric field to the organic semiconductor layer; and
forming a gate insulation film between the organic semiconductor layer and the gate electrode.

19. The manufacturing method of the organic semiconductor element as set forth in claim 18,
wherein said electrode forming process comprises: adhering insulation resin particles or organic semiconductor particles in which metal particulates are dispersed on a layer that is to be a base of the electrode, by using an electrophotographic method; heating the insulation resin particles or the organic semiconductor particles to form a plating seed layer; and applying electroless plating to the plating seed layer to form a metal plating layer.

20. The manufacturing method of the organic semiconductor element as set forth in claim 18,
wherein said gate insulation film forming process comprises: adhering insulation resin particles on a layer that is to be a base of the gate insulation film, by using an electrophotographic method; and heating the insulation resin particles to cure or harden the insulation resin particles.
